(19) United States
(12) Patent Application Publication
(10) Pub. No.: US 2006/0055281 A1
(43) Pub. Date: Mar. 16, 2006

(54) Microelectromechanical electrostatic actuator assembly

(75) Inventor: Bahram Yassini, Waterloo (CA)

Correspondence Address: BERESKIN AND PARR, 40 KING STREET WEST, BOX 401, TORONTO, ON, M5H 3Y2, CA

(73) Assignee: COM DEV Ltd., Cambridge (CA)

(21) Appl. No.: 10/941,860

(22) Filed: Sep. 16, 2004

(51) Int. Cl. H02N 1/00; H01L 41/04

(52) U.S. Cl. 310/309; 318/116

(57) ABSTRACT

A MEMS electrostatic actuator assembly for connection to a DC voltage supply includes a MEMS device and a capacitive element. The MEMS device has a conductive member and a restoring force element. The conductive member is continuously movable between first and second positions in response to the electrostatic force produced by the DC voltage supply. The restoring force element provides a restoring force to the conductive member to move it back to the first position. The capacitive element is coupled in series between the MEMS device and the DC voltage supply and is used to limit the electrostatic force produced within the MEMS device to a value substantially equal to the maximum restoring force provided by the restoring force element.

### FIELD OF THE INVENTION

This invention relates generally to the field of microelectromechanical (MEMS) switches and more particularly to an improved MEMS electrostatic actuator assembly.

### BACKGROUND OF THE INVENTION

Microelectromechanical systems (MEMS) are devices and machines fabricated using techniques generally used in microelectronics, often to integrate mechanical or hydraulic functions etc. with electrical functions. They are based on silicon integrated circuit technologies and allow for the use of mechanical structures, which are flexible and can be moved by magnetic, electric and thermal fields, in addition to electronic components such as resistors, capacitors, diodes, and transistors. For example, MEMS technology is often used to combine computers with tiny mechanical devices such as sensors, valves, gears, mirrors, and actuators embedded in semiconductor chips.

MEMS systems are becoming increasingly important as they replace silicon-based sensors in measuring instruments and control systems. A MEMS device contains micro-circuitry on a tiny silicon chip into which some mechanical device such as a mirror or a sensor has been manufactured. Potentially, such chips can be built in large quantities at low cost, making them cost-effective for many uses. The presently available uses of MEMS or those under study include: global position system sensors built into the fabric of an airplane wing to sense and react to air flow (i.e. changing the wing surface resistance; effectively creating a myriad of tiny wing flaps), optical switching devices that can switch light signals over different paths at 20-nanosecond switching speeds, sensor-driven heating and cooling systems, and building supports with imbedded sensors that can alter the flexibility properties of a material based on atmospheric stress sensing. MEMS devices often utilize electrostatic actuation in components such as variable capacitors, switches, and tunable filters.

FIG. 1 is a schematic diagram illustrating a typical electrostatic MEMS actuation structure 10 which may be used in such devices. The system comprises a movable actuation plate 12, a stationary actuation plate 14, as well as mechanical springs 16 and 18. The actuation plates have area A and are separated by a distance D when the movable actuation plate 12 is in the rest position. When the movable plate 12 is actuated it is displaced by a distance x towards the stationary plate 14. The capacitance Cₘ of plates 12 and 14 is given by the following equation:

$${C}_{m} = \frac{{ɛ}_{0} A}{D - x} \qquad ( 1 )$$

FIG. 2 is a schematic diagram illustrating a typical prior art MEMS device actuator assembly 20. The actuation assembly 20 includes a voltage source 22, a current limiting resistor 24, and a MEMS actuating structure 10. The voltage source 22 causes plates 12 and 14 to be charged and thereby experience an electrostatic force Fe given by the following equation:

$${F}_{e} = \frac{1}{2} \frac{\partial {C}_{m}}{\partial x} {V}_{D C}^{2} = \frac{1}{2} {V}_{D C}^{2} \frac{{ɛ}_{0} A}{{( D - x )}^{2}} \qquad ( 2 )$$

When the movable plate 12 is displaced by a distance x towards the stationary plate 14 the springs 16 and 18 provide a restoring force Fₘ the magnitude of which is given by the following equation:
Fₘ =kₘx, where kₘ is the spring constant (3)

At equilibrium the following equation is true:

$${F}_{e} = {F}_{m} ⇒ \frac{1}{2} {V}_{D C}^{2} \frac{{ɛ}_{0} A}{{k}_{m}} = {x ( D - x )}^{2} \qquad ( 4 )$$

One may define an effective electrostatic force constant kₑ as:

$${k}_{e} = \frac{\partial {F}_{e}}{\partial x} = {V}_{D C}^{2} \frac{{ɛ}_{0} A}{{( D - x )}^{3}} \qquad ( 5 )$$

Thus, the equilibrium condition may be expressed as:

$${k}_{e} = ( \frac{2 x}{D - x} ) {k}_{m} \qquad ( 6 a )$$

From equations (4) and (6a) one can see that the equilibrium criteria may be satisfied until x reaches the critical position x_{c} given by:

$${k}_{e} = {k}_{m} ⇒ {x}_{c} = \frac{D}{3} \qquad ( 6 b )$$

The corresponding voltage across the actuation plates at the position x=x_{c} is called the pull-in voltage Vₚᵢ. A problem with prior art actuation circuits is that once the DC voltage across the MEMS plates 12 and 14 increases beyond this value the equilibrium between the electrostatic force and the mechanical spring force can no longer be maintained. The electrostatic force overpowers the mechanical restoring force of the springs 16 and 18, and thus, the movable MEMS plate 12 will collapse onto the stationary plate 14. One may define the force ratio constant k_{fr} as the ratio of the electrostatic force constant to the spring constant:

$$\begin{matrix}{k}_{fr} = \frac{{k}_{e}}{{k}_{m}} = \frac{{k}_{e}}{{k}_{e} ( {x}_{c} )} = {( \frac{2 D}{3 ( D - x )} )}^{3} forx \geq {x}_{c} & \\ {k}_{fr} = \frac{{k}_{e}}{{k}_{m}} = \frac{2 x}{( D - x )} forx ⊲ {x}_{c} & ( 6 c )\end{matrix}$$

Unfortunately, as can be seen from the above analysis, there are a number of problems associated with MEMS devices that utilize electrostatic actuation systems such as RF MEMS switches and variable capacitors. The main problem is that the moving component such as a bridge/cantilever or the moving plate of a variable capacitor collapses on the actuation pad beyond a certain voltage value or air gap position. Specifically, it is evident from equations (6a), (6b), and (6c) that there is no control over the movable plate 12 once it passes the point ⅓ of the distance between its rest position and the stationary plate 14. With respect to variable capacitors this problem limits the tuning range of final to initial capacitance to approximately 3:1.

The collapsing problem can cause sticking, reduced reliability, contact problems, and generally increase the wear and tear of the device thereby reducing its lifespan. Moreover, to overcome the problem of sticking and effectively pull back the MEMS structure to the rest position a high spring constant is required. This in turn creates the problem of requiring a high DC actuation voltage to overcome the force of the strong spring.

The possibility of collapsing also requires a thin layer of dielectric to be placed between the MEMS actuation pads 12 and 14 in order to ensure that they remain isolated. The addition of the dielectric introduces a new problem in that there is the potential for charge to accumulate within the dielectric. The accumulation of charge impedes the performance of the device in that it interferes with the voltage that is to be created between the actuation pads 12 and 14. The accumulation of charge can, for example, be a problem when the MEMS is exposed to radiation such as in satellite applications.

However, more importantly, simply the application of voltage to the MEMS device during normal operation can cause charge to accumulate and be trapped within the dielectric layer. The presence of this charge is one of the main causes of the sticking (where the moving plate 12 is not released after the voltage has been removed) and failure to actuate (where the device does not actuate properly) problems. Such problems can effectively render the MEMS device useless. Since the charge may accumulate well before other parts of the MEMS device have been worn out this phenomenon can significantly reduce the lifespan of the device. The problems associated with charge accumulation can be completely eliminated by removing the dielectric layer. Thus, there is a real need for a MEMS actuation device that does not utilize a dielectric layer and yet avoids all the problems associated with not having a dielectric layer.

### SUMMARY OF THE INVENTION

The invention provides in one aspect, a MEMS electrostatic actuator assembly for connection to a DC voltage supply, said MEMS electrostatic actuator assembly comprising:
(a) a MEMS device having a conductive member that is continuously movable between a first and a second position in response to a variable electrostatic force produced within the MEMS device by an applied voltage, applied from the DC voltage supply, the MEMS device also having a restoring force element that provides a restoring force to the conductive member to move the conductive member from the second position to the first position; and
(b) a capacitive element coupled in series between the MEMS device and the DC voltage supply for limiting the electrostatic force produced within the MEMS device to a value substantially equal to the maximum restoring force provided by the restoring force element.

The invention provides in another aspect, a MEMS electrostatic actuator assembly for connection to a DC voltage supply, said MEMS electrostatic actuator assembly comprising:
(a) A MEMS device having a member that is continuously movable between a first and a second position in response to a variable electrostatic force produced within the MEMS device by an applied voltage from the DC voltage supply, the MEMS device also having a restoring force element that imparts a restoring force on the member to move the member from the second position to the first position; and
(b) a limiting element coupled in series between the MEMS device and the DC voltage supply for limiting the electrostatic force produced within the MEMS device to a value approximately equal to that provided by the restoring force element.

The invention provides in another aspect, a method of operating a MEMS electrostatic actuator assembly having a capacitive ratio, comprising:
(a) determining a maximum value for a restoring force; and
(b) limiting an electrostatic force produced within the MEMS electrostatic actuator to the maximum value of the restoring force by setting the capacitive ratio to less than a threshold value.

Further aspects and advantages of the invention will appear from the following description taken together with the accompanying drawings.

### BRIEF DESCRIPTION OF THE DRAWINGS

For a better understanding of the present invention, and to show more clearly how it may be carried into effect, reference will now be made, by way of example, to the accompanying drawings which show some examples of the present invention, and in which:

FIG. 1 is a schematic diagram of an electrostatic MEMS actuation structure;

FIG. 2 is a schematic diagram of a prior art MEMS device actuator assembly;

FIG. 3 is a schematic diagram of the MEMS device actuator assembly of the present invention;

FIG. 4 is a graph illustrating the scaled DC voltage applied to the MEMS device as a function of normalized position for various values of B;

FIG. 5 is a graph illustrating the ratio of the required DC source voltage in the assembly of FIG. 3 to the voltage required in the assembly of FIG. 2 at the critical position as well as the corresponding value of the initial capacitance ratio B;

FIG. 6 is a graph plotting the force constant ratio as a function of the normalized position of the moveable MEMS plate for various values of B; and

FIG. 7 is a graph showing the ratio of the voltage across the plates of the MEMS actuation structure to the DC power supply in the assembly of FIG. 3 as well as in the circuit of FIG. 2 as a function of the normalized position of the moveable MEMS plate for various values of the initial capacitance ratio B.

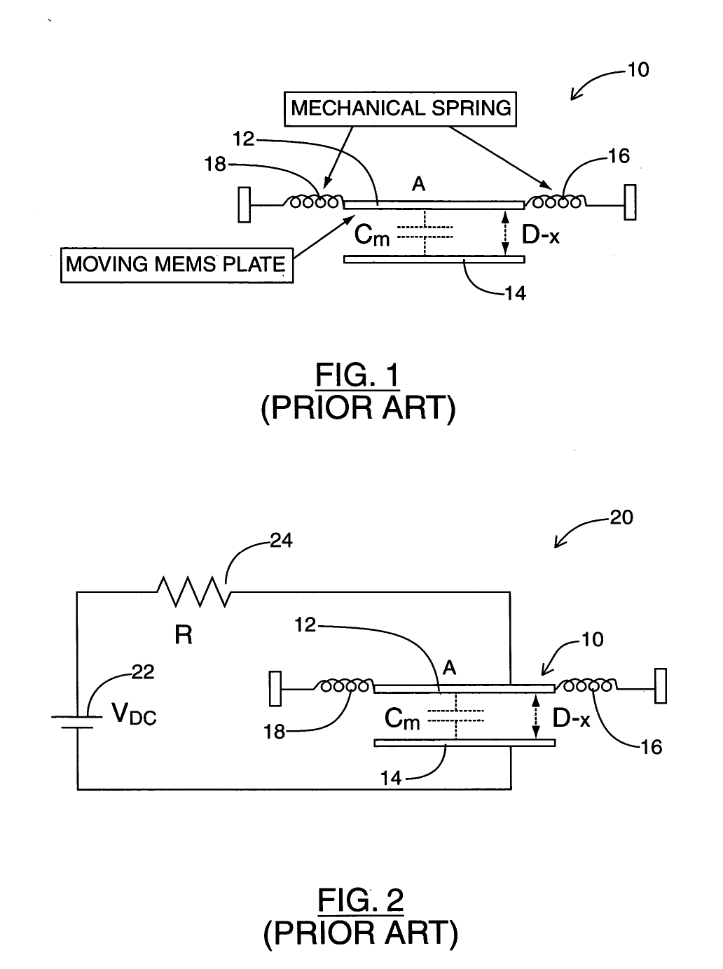

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE INVENTION

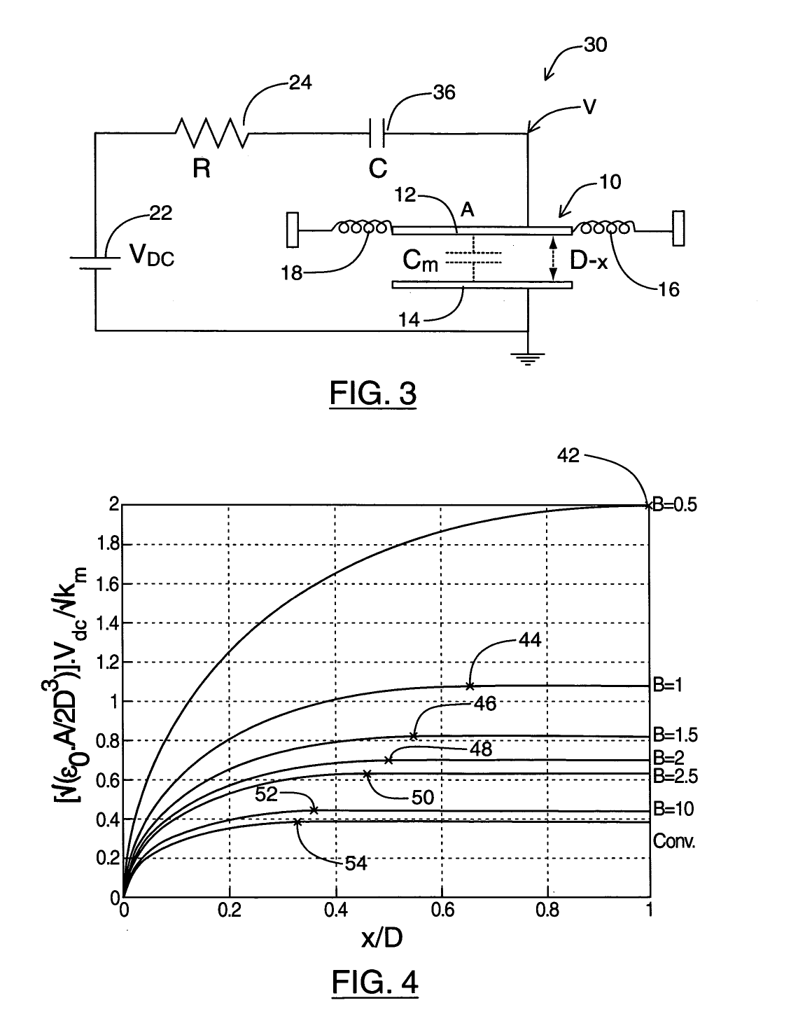

Reference is made to FIG. 3, which is a schematic diagram illustrating the basic elements of a MEMS device actuator assembly 30 made in accordance with a preferred embodiment of the present invention. The actuation circuit 30 includes a voltage source 22, a current limiting resistor 24, a fixed or variable capacitor 36, and a MEMS actuating structure 10. It is preferred that the capacitor 36 be chosen such that DC current leakage is not allowed for and also such that when the MEMS device is to be used for Radio Frequency (RF) applications the capacitor 36 does not support resonance in the frequency range in which the device is intended to be operated.

The DC steady state voltage across the MEMS plates is given by the voltage division rule and may be expressed as follows:

$$V = {V}_{D C} \frac{C}{C + {C}_{m}} \qquad ( 7 )$$

The expression for the electrostatic force Fₑ between the two MEMS plates may be found by substituting V of equation (7) into V_{DC} Of equation (2), which yields:

$${F}_{e} = \frac{1}{2} {V}_{D C}^{2} \frac{{C}^{2}}{{( C + {C}_{m} )}^{2}} \frac{{ɛ}_{0} A}{{( D - x )}^{2}} \qquad ( 8 )$$

One may also define the initial capacitance ratio B to be the ratio of the series capacitance 36 to the capacitance of the MEMS plates 12 and 14 when the movable plate 14 is in its rest position. The series capacitance 36 can then be expressed as:

$$C = B \frac{{ɛ}_{0} A}{D} \qquad ( 9 )$$

Substituting equations (1) and (9) into equation (8), one may express the electrostatic force between the MEMS plates as:

$${F}_{e} = \frac{1}{2} {V}_{D C}^{2} {ɛ}_{0} {A ( \frac{B}{( B + 1 ) D - Bx} )}^{2} \qquad ( 10 )$$

It can be observed from equation (10) that the assembly constructed in accordance with the present invention the electrostatic force has an upper bound and does not tend towards infinity when the movable MEMS plate approaches the stationary plate as it does in the conventional MEMS actuator assembly as seen in the relationship of equation (2). The maximum electrostatic force experienced between the MEMS plates is given by:

$${F}_{e} ( x -> D ) = \frac{1}{2} {V}_{D C}^{2} {ɛ}_{0} {A ( \frac{B}{D} )}^{2} \qquad ( 11 )$$

Since the electrostatic force in an assembly built in accordance with the present invention is bounded, so is the required mechanical restoring force of the springs 16 and 18. Thus, an advantage of the present invention is that weaker mechanical springs may be used than in prior art devices and consequently the required DC voltage across the MEMS plates 12 and 14 is lower.

At equilibrium the electrostatic force must equal the spring restoring force and therefore the following relationship must hold:

$${F}_{e} = {F}_{m} ⇒ \frac{1}{2} {V}_{D C}^{2} \frac{{ɛ}_{0} A}{{k}_{m}} = {( \frac{( B + 1 ) D - Bx}{B} )}^{2} x \qquad ( 12 )$$

It should be understood that for purposes of this description, the spring constant kₘ has been assumed to be linear (i.e. not to be a function of the gap x). This is a reasonable assumption for most embodiments of the invention, with the exception of the cantilever type switch. For the cantilever type switch, it may be necessary to model the spring constant kₘ as a non-linear value. Such non-linearity could affect the threshold value for the initial capacitance ratio B and the critical position.

Defining the effective electrostatic force constant kₑ as:

$${k}_{e} = \frac{\partial {F}_{e}}{\partial x} {V}_{D C}^{2} {ɛ}_{0} {A ( \frac{B}{( B + 1 ) D - Bx} )}^{3} \qquad ( 13 )$$

Rewriting equation (10) in terms of the electrostatic force constant defined in equation (13) yields:

$${F}_{e} = {k}_{e} ( \frac{( B + 1 ) D - Bx}{B} ) \qquad ( 14 )$$

Equating equations (14) and (3) yields the following equilibrium condition:

$${k}_{e} = ( \frac{2 Bx}{( B + 1 ) D - {B}_{x}} ) {k}_{m} \qquad ( 15 )$$

The critical position x_{c} is given by the following relationship:

$${k}_{e} = {k}_{m} ⇒ {x}_{c} = ( \frac{B + 1}{B} ) \frac{D}{3} \qquad ( 16 )$$

From equation (16) it is evident that the following is true:
B=0.5x_{c}=D
B>0.5x_{c}<D
B<0.5x_{c}>D (17)

As is evident from equation (17) in an actuation assembly built in accordance with the present invention there is no critical position when the initial capacitance ratio B is less than 0.5. Therefore, the pull-in effect does not occur under such conditions and the MEMS plate does not collapse onto the stationary plate. Thus, an equilibrium position is achievable at all points in the air gap between the rest position of the MEMS movable plate 12 and the stationary plate 14.

It should be understood that the MEMS actuation assembly 10 would generally considered to be part of a MEMS device. For example, the moving electrode of a MEMS switch and contact would be mapped on the same material within the MEMS and move up and down together.

Reference is now made to FIG. 4 which is a graph illustrating a value proportional to the DC voltage applied across the MEMS plates 12 and 14 as a function of normalized position for various values of the initial capacitance ratio B. From the variable on the y-axis one may see that there is a tradeoff between the actuation voltage and the spring constant. Specifically for a given value of B, the actuation voltage may be reduced by half if the spring constant is reduced by a quarter.

The normalized critical position in a circuit constructed in accordance with the present invention for values of B equal to 0.5, 1, 1.5, 2, 2.5, and 10 are indicated at 42, 44, 46, 48, 50 and 52 respectively. The normalized critical position for a prior art circuit is shown at 54. As can be seen, as the value of B decreases, the critical position moves closer to the stationary plate 14. In addition, it is also apparent that any position in the air gap is achievable when the value of B is less than or equal to 0.5.

Thus, it is possible to construct an assembly in accordance with the present invention in which the position of the moveable plate can be adjusted over the full range of the air gap without collapsing. Consequently, in such an embodiment, there is no need for a dielectric layer between the MEMS plates 12 and 14. Therefore, the problem of charge accumulation in the dielectric layer is no longer present. This is an important benefit given that, as explained above, the retention of charge within the dielectric layer is one of the main causes of problems such as sticking and the failure to actuate. This is also particularly beneficial where the MEMS device is exposed to radiation.

The greater degree of control and avoidance of collapsing leads to other benefits as well. Specifically, sticking problems do not occur and there is less wear and tear on the MEMS system allowing for greater reliability and a longer lifespan.

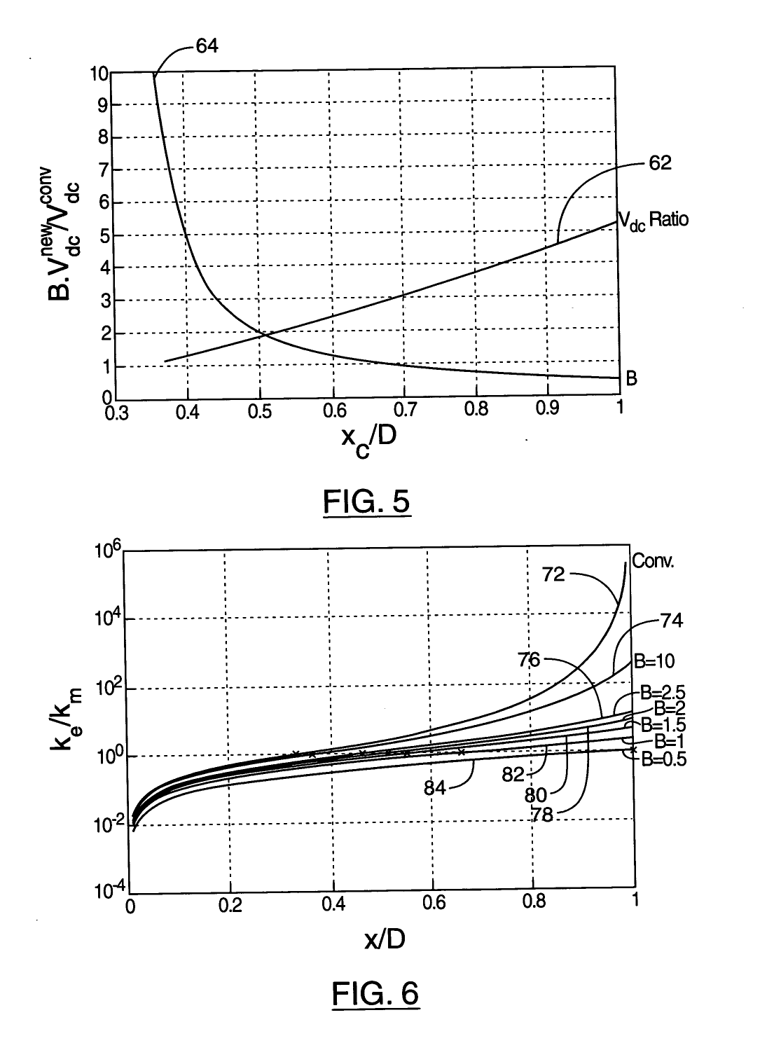

Reference is now made to FIG. 5 which is a graph illustrating, in line 62, the ratio of the required DC voltage in an assembly made in accordance with a preferred embodiment of the present invention to the voltage required in a conventional circuit as a function of the normalized critical distance. Also indicated, as curve 64, is the corresponding value of B

The force constant k_{fr} can be calculated as follows:

$$\begin{matrix}{k}_{fr} = \frac{{k}_{e}}{{k}_{m}} = \frac{{k}_{e}}{{k}_{e} ( {x}_{c} )} = {( \frac{( B + 1 ) D - {Bx}_{c}}{( B + 1 ) D - Bx} )}^{3} for x \geq {x}_{c} & \\ {k}_{fr} = \frac{{k}_{e}}{{k}_{m}} = ( \frac{2 Bx}{( B + 1 ) D - Bx} ) for x ⊲ {x}_{c} & ( 18 )\end{matrix}$$

From equation (18) one may calculate a maximum force ratio as follows:

$${k}_{fr}^{MAX} = \frac{{k}_{e}}{{k}_{m}} = {( \frac{2 ( B + 1 )}{3} )}^{3} for x -> D , and B \geq 0.5 \qquad ( 19 )$$

Thus, it has been shown that in an assembly built in accordance with the present invention there is an upper bound to the force ratio even when the value of B is greater than 0.5 and a critical position exists. Therefore, there is a limit on how strong a spring is required.

FIG. 6 is a graph showing, as curves 74 through 84, the force constant ratio k_{fr} for different values of B in an assembly constructed in accordance with a preferred embodiment of the present invention. Also shown, as curve 72, is the force constant ratio in a conventional prior art assembly. It is evident from the graph that whereas, in the assembly made in accordance with the present invention the force constant ratio is bounded, the force constant ratio in a conventional prior art circuit is unbounded.

For this reason as well as the fact that the circuit 30 when made in accordance with a preferred embodiment of the present invention, the critical position is closer to the stationary plate 14 than in a conventional prior art system, the pull-in effect is not as strong or problematic in the former assembly as it is in the latter. Consequently, a weaker MEMS spring can overcome the pull-in effect impacts on the MEMS structure and provide the restoring force necessary to pull the movable MEMS plate 12 back to its rest position once the DC voltage is removed.

For values of B less than or equal to 0.5, the pull-in effect does not occur in assemblies made in accordance with the present invention and therefore, the movable plate 12 does not collapse on the stationary plate 14. Thus, regardless of the value of B, a MEMS device actuator assembly 30 made in accordance with the present invention benefits from being able to use a spring with a lower spring constant as compared with the conventional prior art system. Since less force is required to move such a spring, a smaller voltage is required across the MEMS actuation structure 10.

In an assembly made in accordance with the present invention, the ratio of the voltage across the MEMS actuation system to the DC voltage of power supply 22 can be determined by substituting equation (9) into equation (7):

$$\frac{V}{{V}_{D C}} = \frac{B ( D - x )}{B ( D - x ) - D} \qquad ( 20 )$$

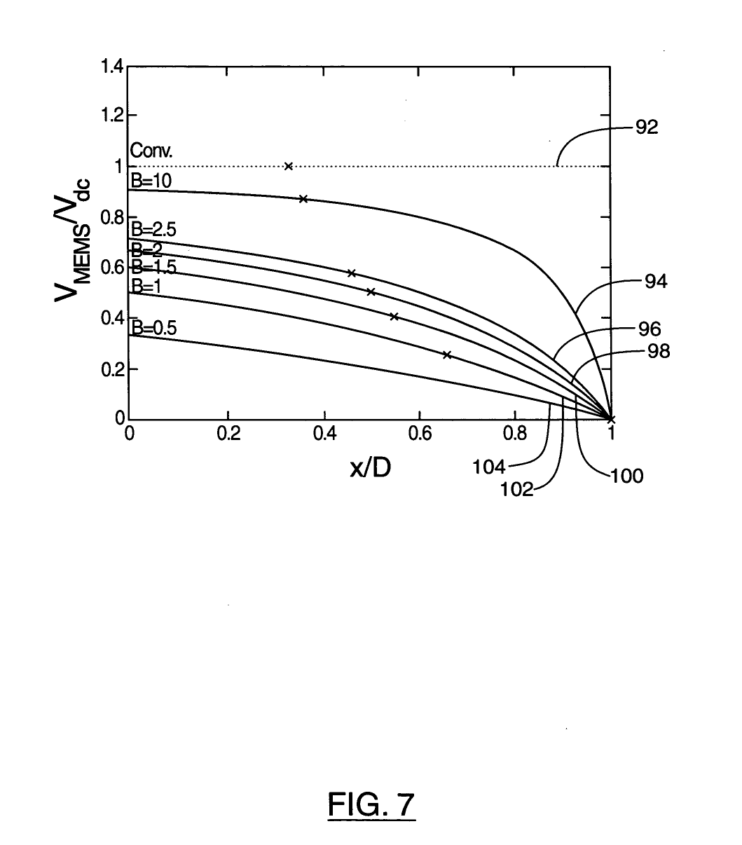

FIG. 7, is a graph illustrating the ratio of equation (20) as a function of normalized displacement of the moveable plate 12. Curves 94 through 104 show this ratio for an assembly built in accordance with the present invention for various values of B. Line 92 indicates this ratio for a conventional prior art assembly. It is apparent from equation (20) and the graph of FIG. 7 that regardless of the value of the capacitance ratio, as the movable plate 12 approaches the stationary plate 14, the voltage across the MEMS actuation system 10 tends to 0 V. Consequently, sharp current spikes and sudden discharges of the MEMS capacitance or any charge trapping issues in the insulator dielectric layer between MEMS actuation plates 12 and 14 and resulting problems such as sticking or failure to actuate are prevented.

It is contemplated that the actuator assembly 10 is applicable to a wide variety of applications including but not limited to variable capacitors and bridge or cantilever type switches whether connected in series or shunt configurations, as well as applications which utilize such devices such as MEMS filters, tunable filters and filter banks. In fact, almost any MEMS device utilizing electrostatic actuation can benefit from this invention. Specifically, the relations and equations discussed above are equally applicable to a MEMS bridge. The cantilever type switch also benefits from this invention as long as the electrostatic actuation is utilized.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

1. A MEMS electrostatic actuator assembly for connection to a DC voltage supply, said MEMS electrostatic actuator assembly comprising:
(a) a MEMS device having a conductive member that is continuously movable between a first and a second position in response to a variable electrostatic force produced within the MEMS device by an applied voltage, applied from the DC voltage supply, the MEMS device also having a restoring force element that provides a restoring force to the conductive member to move the conductive member from the second position to the first position; and
(b) a capacitive element coupled in series between the MEMS device and the DC voltage supply for limiting the electrostatic force produced within the MEMS device to a value substantially equal to the maximum restoring force provided by the restoring force element.

2. The MEMS electrostatic actuator assembly of claim 1, wherein the conductive member of the MEMS device is a movable MEMS plate and the MEMS device further comprises a conductive fixed plate, the movable MEMS plate being suspended in parallel above the conductive fixed plate at a first voltage level and the movable MEMS plate forced into contact with the conductive fixed plate at a second voltage.

3. The MEMS electrostatic actuator assembly of claim 2, wherein the restoring force element is a spring that is connected to the movable MEMS plate.

4. The MEMS electrostatic actuator assembly of claim 3, wherein the capacitance ratio, between the capacitive element and an initial equivalent capacitance provided by the MEMS device when the movable MEMS plate is in the first position, is less than or equal to 0.5.

5. The MEMS electrostatic actuator assembly of claim 3, wherein the capacitance ratio, between the capacitive element and an initial equivalent capacitance provided by the MEMS device when the movable MEMS plate is in the first position, is greater than 0.5.

6. The MEMS electrostatic actuator assembly of claim 4 integrated into a solid-state circuit and providing a tunable value of capacitance to the solid-state circuit.

7. The MEMS electrostatic actuator assembly of claim 1, wherein the capacitive element is a fixed capacitor.

8. The MEMS electrostatic actuator assembly of claim 1, wherein the capacitive element is a tunable capacitor.

9. A MEMS electrostatic actuator assembly for connection to a DC voltage supply, said MEMS electrostatic actuator assembly comprising:
(a) A MEMS device having a member that is continuously movable between a first and a second position in response to a variable electrostatic force produced within the MEMS device by an applied voltage from the DC voltage supply, the MEMS device also having a restoring force element that imparts a restoring force on the member to move the member from the second position to the first position; and
(b) a limiting element coupled in series between the MEMS device and the DC voltage supply for limiting the electrostatic force produced within the MEMS device to a value approximately equal to that provided by the restoring force element.

10. The MEMS electrostatic actuator assembly of claim 9, wherein the limiting element is a capacitor.

11. The MEMS electrostatic actuator assembly of claim 9, wherein the limiting element is circuit providing a capacitance.

12. A method of operating a MEMS electrostatic actuator assembly having a capacitive ratio, comprising:
(a) determining a maximum value for a restoring force; and
(b) limiting an electrostatic force produced within the MEMS electrostatic actuator to the maximum value of the restoring force by setting the capacitive ratio to less than a threshold value.

13. The method of claim 12, wherein the threshold value is 0.5.

14. The method of claim 12, wherein the electrostatic actuator includes a capacitor and where the assembly is actuated by adjusting the capacitive ratio by changing the value of the capacitor.
